(19) United States
(12) Patent Application Publication
(10) Pub. No.: US 2009/0068840 A1
(43) Pub. Date: Mar. 12, 2009

(54) POLISHING LIQUID AND METHOD FOR MANUFACTURING SEMICONDUCTOR DEVICE

(76) Inventors: Gaku MINAMIHABA, Yokohama-shi (JP); Shunsuke Doi, Yokkaichi-shi (JP); Nobuyuki Kurashima, Yokohama-shi (JP); Yoshikuni Tateyama, Hiratasuka-shi (JP); Hiroyuki Yano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/200,388

(22) Filed: Aug. 28, 2008

(30) Foreign Application Priority Data
Aug. 31, 2007 (JP) 2007-226085

(51) Int. Cl. H01L 21/304; C09K 3/14

(52) U.S. Cl. 438/693; 51/308; 257/E21.23

(57) ABSTRACT

A polishing liquid is provided, which includes abrasive grains and a surfactant. The abrasive grains contain a first colloidal silica having an average primary particle diameter of 45-80 nm and a second colloidal silica having an average primary particle diameter of 10-25 nm. The weight w₁ of the first colloidal silica and the weight w₂ of the second colloidal silica satisfy the relationship represented by the following expression 1.

0.63≦w₁/(w₁+w₂)≦0.83 Expression 1

### CROSS-REFERENCE TO RELATED APPLICATIONS

This application is based upon and claims the benefit of priority from prior Japanese Patent Application No. 2007-226085, filed Aug. 31, 2007, the entire contents of which are incorporated herein by reference.

### BACKGROUND OF THE INVENTION

1. Field of the Invention

This invention relates to a polishing liquid for CMP (Chemical Mechanical Polishing) and to a method for manufacturing a semiconductor device.

2. Description of the Related Art

One of the subject matters in a high-performance LSI of the next generation is how to minimize the parasitic capacity of wiring made of Cu, etc. When the relative dielectric constant (k) of insulating film materials is reduced, Young's modulus decreases, and the insulating film materials become vulnerable to mechanical damage that may result from CMP. Further, since the surface of the insulating film of low dielectric constant is hydrophobic, a polishing liquid comprising water as a solvent may be repelled by the surface of the insulating film of low dielectric constant. As a result, the enlargement and adhesion of abrasive grains are more likely to occur, giving rise to abnormal polishing and making it difficult to sufficiently inhibit the generation of scratches. It is considered possible, by a film (SiOC film) of around 2.6 in “k” and around 10 GPa in Young's modulus, to create a Low-k/Cu wiring which is free from peeling of film even after the CMP thereof.

However, unless it is possible to remarkably minimize the generation of scratches that may be caused due to CMP, it is difficult to mass-produce a high-performance LSI of good yield and reliability of wiring.

The present inventors have proposed in U.S. Pat. No. 7,060,621 a polishing liquid containing two kinds of colloidal particles differing in primary particle diameter. Using this polishing liquid, it is possible to perform the polishing of a Ta film, an SiO₂ film, etc. while making it possible to suppress the generation of erosion and scratches. However, in contrast to the Ta film and SiO₂ film, which are hard materials, an SiOC film is vulnerable to mechanical damage, so that when this polishing liquid is applied to the SiOC film, it may become difficult to minimize the generation of scratches.

U.S. Pat. No. 6,935,928 describes that the conventional polishing liquid for a barrier metal film contains colloidal silica as abrasive grains and is alkaline. Although it is possible with this polishing liquid to polish an SiOC film, it is impossible to avoid the generation of scratches. Therefore, there are persistent demands for the development of a polishing liquid which makes it possible to remarkably minimize the generation of scratches on the surface of the SiOC film.

### BRIEF SUMMARY OF THE INVENTION

A polishing liquid according to one aspect of the present invention comprises:

abrasive grains containing a first colloidal silica having an average primary particle diameter of 45-80 nm and a second colloidal silica having an average primary particle diameter of 10-25 nm, the weight w₁ of the first colloidal silica and the weight w₂ of the second colloidal silica satisfying the relationship represented by the following expression 1; and

a surfactant:

0.63≦w₁/(w₁+w₂)≦0.83 Expression 1.

A method for manufacturing a semiconductor device according to one aspect of the present invention comprises:

forming a plurality of rib-like wirings above a semiconductor substrate;

depositing an SiOC film above the rib-like wirings while creating a void space between neighboring rib-like wirings; and

polishing the SiOC film with a polishing liquid, the polishing liquid comprising abrasive grains containing a first colloidal silica having an average primary particle diameter of 45-80 nm and a second colloidal silica having an average primary particle diameter of 10-25 nm, the weight w₁ of the first colloidal silica and the weight w₂ of the second colloidal silica satisfying the relationship represented by the following expression 1; and a surfactant:

0.63≦w₁/(w₁+w₂)≦0.83 Expression 1.

A method for manufacturing a semiconductor device according to another aspect of the present invention comprises:

depositing a wiring material film above an SiOC film having a recess and in the recess with a barrier metal being interposed between the wiring material film and the SiOC film, the SiOC film being formed above a semiconductor substrate;

removing the wiring material film except the wiring material film deposited in the recess, thereby leaving the wiring material film in the recess while selectively exposing the barrier metal; and

polishing and removing the barrier metal except the barrier metal deposited in the recess with a polishing liquid, thereby exposing the SiOC film, the polishing liquid comprising abrasive grains containing a first colloidal silica having an average primary particle diameter of 45-80 nm and a second colloidal silica having an average primary particle diameter of 10-25 nm, the weight w₁ of the first colloidal silica and the weight w₂ of the second colloidal silica satisfying the relationship represented by the following expression 1; a surfactant; an oxidizing agent; and an oxidation inhibitor:

0.63≦w₁/(w₁+w₂)≦0.83 Expression 1.

### BRIEF DESCRIPTION OF THE SEVERAL VIEWS OF THE DRAWING

FIG. 1 shows a diagram schematically explaining a state in the execution of CMP;

FIG. 2 is a cross-sectional view illustrating a step in the manufacturing method of a semiconductor device according to one embodiment of the present invention;

FIG. 3 is a cross-sectional view illustrating a step following the step shown in FIG. 2;

FIG. 4 is a cross-sectional view illustrating a step following the step shown in FIG. 3;

FIG. 5 is a cross-sectional view illustrating a step following the step shown in FIG. 4;

FIG. 6 is a cross-sectional view illustrating a step following the step shown in FIG. 5;

FIG. 7 is a cross-sectional view illustrating a step following the step shown in FIG. 6;

FIG. 8 is a cross-sectional view illustrating a step following the step shown in FIG. 7;

FIG. 9 is a cross-sectional view illustrating a step following the step shown in FIG. 8;

FIG. 10 is a cross-sectional view illustrating a step following the step shown in FIG. 9; and

FIG. 11 is a cross-sectional view illustrating a step following the step shown in FIG. 10.

### DETAILED DESCRIPTION OF THE INVENTION

Next, embodiments of the present invention will be explained with reference to drawings.

The polishing liquid according to one embodiment of the present invention contains colloidal silica as abrasive grains, and a surfactant. This colloidal silica can be synthesized by the hydrolysis of silicon alkoxide compounds by a sol-gel method, examples of silicon alkoxide compounds including Si(OC₂H₅)₄, Si(sec-OC₄H₉)₄, Si(OCH₃)₄ and Si(OC₄H₉)₄.

An average primary particle diameter of colloidal silica to be obtained is generally confined within the range of 5-2000 nm. This average primary particle diameter of colloidal silica can be determined by SEM or TEM observation. For example, a photograph of the colloidal silica is taken at a magnification of 100-500 thousands times by SEM observation. Then, the largest particle diameter of colloidal silica is measured by calipers to determine the primary particle diameter of the colloidal silica. The measurement of this primary particle diameter of the colloidal silica is repeated 300 times using 300 colloidal silica particles to determine a particle size cumulative curve, on the basis of which a primary particle diameter of colloidal silica which falls within 50% of the particle size cumulative curve is calculated to determine the average primary particle diameter of colloidal silica.

According to one embodiment of the present invention, the abrasive grains are constituted by two kinds of colloidal silica differing in average primary particle diameter. A first colloidal silica has an average primary particle diameter of 45-80 nm. This first colloidal silica mainly serves to polish a polishing film (i.e. film to be polished). If the average primary particle diameter of the first colloidal silica is less than 45 nm, it would become impossible to obtain a sufficient polishing power and, additionally, it would become impossible to minimize the generation of scratches. On the other hand, if the average primary particle diameter of the first colloidal silica is larger than 80 nm, not only the scratches but also the erosion of polishing film may generate. More preferably, the average primary particle diameter of the first colloidal silica should be limited to 50 to 60 nm.

A second colloidal silica has an average primary particle diameter of 10-25 nm. This second colloidal silica serves to suppress the micro-flocculation of the first colloidal silica during the polishing of a polishing film. Further, it is assumed that this second colloidal silica is capable of preventing the first colloidal silica from excessively intruding into a polishing film, thereby functioning to protect the polishing film. If the average primary particle diameter of the second colloidal silica is less than 10 nm, the second colloidal silica itself may be flocculated, thereby making it impossible to suppress the micro-flocculation of the first colloidal silica. On the other hand, if the average primary particle diameter of the second colloidal silica is larger than 25 nm, the effects thereof to suppress the micro-flocculation of the first colloidal silica would be deteriorated and, additionally, the effects thereof to protect the polishing film from the first colloidal silica would be reduced. More preferably, the average primary particle diameter of the second colloidal silica should be limited to 15 to 20 nm.

It has been found out by the present inventors that when the first colloidal silica and the second colloidal silica, each having the above-described average primary particle diameter, are mixed with each other at a ratio indicated below when using, as abrasive grains, a mixture comprising the first colloidal silica and the second colloidal silica, it is possible to suppress the generation of scratches on the surface of an SiOC film.

0.63≦w₁/(w₁+w₂)≦0.83 (1)

(wherein w₁ is a weight of the first colloidal silica and w₂ is a weight of the second colloidal silica in a polishing liquid)

Further, it has been found out that as long as the relationship represented by the following expression (2) is satisfied, it is possible to sufficiently minimize the generation of scratches on the surface of an SiOC film.

0.67≦w₁/(w₁+w₂)≦0.77 (2)

The polishing liquid according to one embodiment of the present invention can be prepared by dispersing the first colloidal silica and the second colloidal silica in water such as pure water. The abrasive grains consisting of a mixture comprising the first colloidal silica and the second colloidal silica are preferably incorporated in a polishing liquid at a content of 1 to 10% by weight based on a total weight of the polishing liquid.

If the content of the abrasive gains is less than 1% by weight, it would be impossible to polish the SiOC film at a practical polishing rate. On the other hand, if the content of the abrasive gains is larger than 10% by weight, there is a possibility of causing erosion and scratches when polishing a polishing film using the polishing liquid containing the aforementioned abrasive grains. More preferably, the content of the abrasive gains should be confined to 3 to 8% by weight.

The polishing liquid according to one embodiment of the present invention is applicable to the CMP wherein the surface to be polished is constituted by the surface of a SiOC film for planarizing the SiOC film for example. Since the SiOC film is hydrophobic, the surface thereof is poor in affinity to water. In order to improve the affinity of the surface of SiOC film to water, a surfactant is incorporated in the polishing liquid according to one embodiment of the present invention.

As the surfactant, it is possible to employ an anionic surfactant, a cationic surfactant or a nonionic surfactant. Examples of the anionic surfactant include dodecylbenzene sulfonic acid and salts thereof, and polyacrylic acid and salts thereof. Examples of the cationic surfactant include polyoxyethylene alkylamine. Examples of the nonionic surfactant include polyoxyethylene lauryl ether, acetylenediol-based ethylene oxide adduct, perfluoroalkyl ethylene oxide adduct, polyvinylpyrrolidone (PVP) and polyvinyl alcohol (PVA).

The content of the surfactant in the polishing liquid should preferably be confined to 0.0001-1% by weight, more preferably 0.001-0.1% by weight based on a total weight of the polishing liquid. When the content of the surfactant is too low, it may be impossible to secure the effects of the surfactant. When the content of the surfactant is excessively high, i.e., exceeding 1% by weight, the polishing rate of an SiOC film would be greatly reduced and, still more, the viscosity of the polishing liquid increases, giving rise to such a problem that it becomes difficult to feed the polishing liquid onto the polishing table. Incidentally, the surfactant may be utilized also as a polishing-rate-adjusting agent for the SiOC film.

Among the aforementioned surfactants, acetylenediol-based ethylene oxide adduct, dodecylbenzene sulfonic acid and salts thereof, polyacrylic acid and salts thereof, and PVA are especially effective in minimizing the generation of erosion and scratches when polishing.

When the stability of polishing liquid and the adsorptivity of polishing liquid to the SiOC film are taken into account in the cases where nonionic surfactants are to be employed, the HLB value according to Griffin's formula is preferably be limited to 7-18.

Since the polishing liquid according to the embodiment of the present invention contains two kinds of colloidal silica which are mixed together at a specific ratio and are respectively regulated in average primary particle diameter, and a surfactant, it is possible to minimize the generation of scratches that may be created on the surface of SiOC film.

When additives such as an oxidizing agent and an oxidation inhibitor are incorporated in the polishing liquid in addition to the aforementioned components, the polishing liquid according to the embodiment of the present invention can be applied to the polishing of a metallic film, such as a Cu film which is buried in an SiOC film.

As the oxidizing agent, it is possible to employ, for example, ammonium persulfate, potassium persulfate, hydrogen peroxide, etc. As long as the oxidizing agent is incorporated in the polishing liquid at a content of 0.1-5% by weight, the effects of the oxidizing agent can be exhibited without increasing the generation of scratches of the SiOC film.

With respect to the oxidation inhibitor, it is possible to employ organic acid and amino acid. Examples of the organic acid include heterocyclic organic compound such as quinaldinic acid, quinolinic acid, and benzotriazole (BTA), malonic acid, oxalic acid, citric acid, maleic acid, phthalic acid, nicotinic acid, picolinic acid, succinic acid, etc. Examples of the amino acid include glycine, alanine, etc.

As long as the oxidation inhibitor is incorporated in the polishing liquid at a content of 0.01-3% by weight, the effects of the oxidation inhibitor can be exhibited without increasing the generation of scratches of the SiOC film.

Because of the availability through industrial mass production and of the easiness of washing even with the conventional washing liquid, of the aforementioned oxidation inhibitors, quinaldinic acid, quinolinic acid, maleic acid and glycine is more preferable.

The pH of the polishing liquid according to the embodiment of the present invention is preferably confined to a region of 8-11. As long as the pH is regulated within this range, it is possible to realize a practical polishing rate of the SiOC film. The pH of the polishing liquid can be regulated by a pH adjustor, examples of which including KOH, ammonia solution, TMAH (tetramethyl ammonium hydroxide), etc. The higher the pH is, the higher the polishing rate of the SiOC film becomes.

### EMBODIMENT 1

Colloidal silica having an average primary particle diameter (d₁) of 50 nm was prepared as a first colloidal silica. As a second colloidal silica, six kinds of particles differing in average primary particle diameter (d₂) were prepared. Namely, the average primary particle diameter of the second colloidal silica was set to 7 nm, 10 nm, 15 nm, 20 nm, 25 nm and 30 nm.

The first colloidal silica and the second colloidal silica were mixed together in such a way that the mixing ratio (w₁/(w₁+w₂)) thereof would become a predetermined value, thus preparing plural kinds of abrasive grains. Herein, w₁ means the weight of the first colloidal silica, and w₂ means the weight of the second colloidal silica. The mixing ratio was set to 0.59, 0.63, 0.67, 0.71, 0.77, 0.83 and 0.91.

The mixing ratio (w₁/(w₁+w₂)) in each sample of abrasive grains is summarized in the following Table 1 together with the average primary particle diameter (d₂) of the second colloidal silica.

TABLE 1

| | d₂ | |
|---|---|---|
| No. | (nm) | w₁/(w₁ + w2) |
| 1 | 7 | 0.59 |
| 2 | 10 | |
| 3 | 15 | |
| 4 | 20 | |
| 5 | 25 | |
| 6 | 30 | |
| 7 | 7 | 0.63 |
| 8 | 10 | |
| 9 | 15 | |
| 10 | 20 | |
| 11 | 25 | |
| 12 | 30 | |
| 13 | 7 | 0.67 |
| 14 | 10 | |
| 15 | 15 | |
| 16 | 20 | |
| 17 | 25 | |
| 18 | 30 | |
| 19 | 7 | 0.71 |
| 20 | 10 | |
| 21 | 15 | |
| 22 | 20 | |
| 23 | 25 | |
| 24 | 30 | |
| 25 | 7 | 0.77 |
| 26 | 10 | |
| 27 | 15 | |
| 28 | 20 | |
| 29 | 25 | |
| 30 | 30 | |
| 31 | 7 | 0.83 |
| 32 | 10 | |
| 33 | 15 | |
| 34 | 20 | |
| 35 | 25 | |
| 36 | 30 | |
| 37 | 7 | 0.91 |
| 38 | 10 | |
| 39 | 15 | |
| 40 | 20 | |
| 41 | 25 | |
| 42 | 30 | |

5% by weight of each sample of the abrasive grains thus obtained, and 0.005% by weight of acetylenediol ethylene oxide adduct (HLB value: 18) as a surfactant were mixed with pure water to obtain a mixture. Further, the pH of the mixture was adjusted to 10.5 with ammonia solution to prepare a plurality of polishing liquids.

Using each polishing liquid, an SiOC film was polished and the generation of scratches on the surface of the SIOC film was investigated after the polishing thereof. In the cases of the polishing liquids employed herein, the polishing rate of the SiOC film was found falling within the range of 50-80 nm/min. The polishing rate of the SiOC film could be adjusted by suitably selecting the concentration of abrasive grains, the kinds and concentration of the surfactant, and the pH of the polishing liquid.

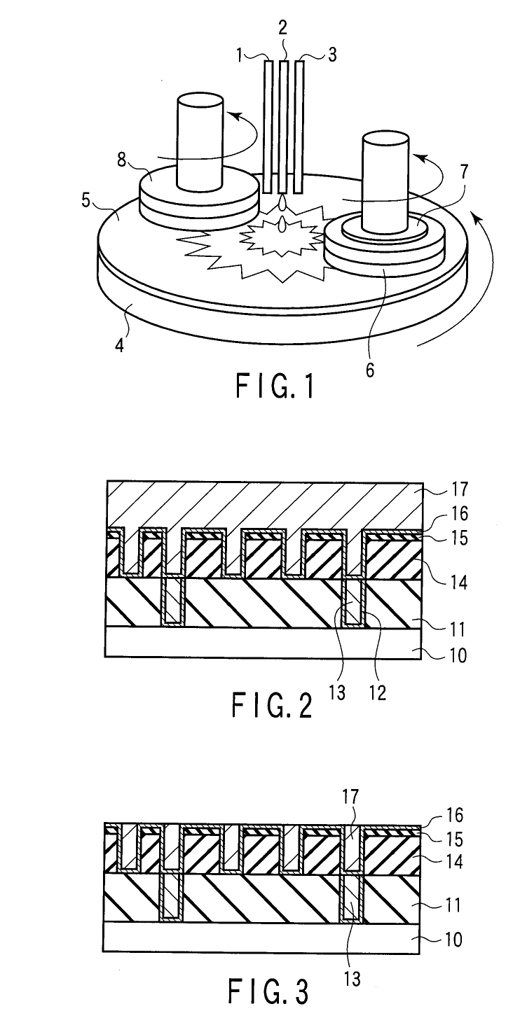

For the polishing of the SiOC film, the SiOC film was deposited to a thickness of 160 nm on a semiconductor substrate having a diameter of 300 mm, thus preparing a polishing substrate. The polishing was performed under the conditions wherein, as shown in FIG. 1, a turntable 4 having a polishing pad (IC1000: Nitta Haas Co., Ltd.) 5 attached thereto was kept rotating at a rotational speed of 100 rpm, and a top ring 7 holding a semiconductor substrate 6 was in contact with the polishing pad 5 at a polishing load of 300 gf/cm². The rotational speed of the top ring 7 was set to 102 rpm. The polishing of the SiOC film was performed for 60 seconds while feeding the polishing liquid from a polishing liquid supply nozzle 2 onto the surface of polishing pad 5 at a flow rate of 300 cc/min. FIG. 1 also shows a pure water supply nozzle 1, a washing liquid supply nozzle 3 and a dresser 8.

Then, the surface of the SiOC film after polishing was investigated for the number of scratches by a defectives evaluation apparatus KLA (trade name)(Tencor Co., Ltd.). The evaluation was performed under the following criterion based on the number of scratches per sheet of wafer. When the number of scratches was less than 100, it was assumed as acceptable.

⊚: Less than 10

◯: 10 or more and less than 30

Δ: 30 or more and less than 100

×: 100 or more

The results of polishing using these polishing liquids are summarized in the following Table 2.

TABLE 2

d2 (nm)

| | | 7 | 10 | 15 | 20 | 25 | 30 |
|---|---|---|---|---|---|---|---|
| w₁/(w₁ + w2) | 0.59 | X | X | X | X | X | X |
| | 0.63 | X | Δ | ◯ | ◯ | Δ | X |
| | 0.67 | X | Δ | ⊚ | ⊚ | Δ | X |
| | 0.71 | X | ◯ | ⊚ | ⊚ | Δ | X |
| | 0.77 | X | ◯ | ⊚ | ⊚ | ◯ | X |
| | 0.83 | X | Δ | ◯ | ◯ | Δ | X |
| | 0.91 | X | X | X | X | X | X |

As shown in above Table 2, when the first colloidal silica having an average primary particle diameter (d₁) of 50 nm was employed, the second colloidal silica was required to have an average primary particle diameter (d₂) ranging from 10 to 25 nm, and the mixing ratio thereof (w₁/(w₁+w₂)) was required to be confined within the range of 0.63 to 0.83 in order to suppress the generation of scratches to be within the tolerance limits.

Particularly, when the second colloidal silica having an average primary particle diameter (d₂) ranging from 15 to 20 nm was employed and the mixing ratio thereof (w₁/(w₁+w₂)) was confined to 0.67 to 0.77, it was possible to greatly minimize the generation of scratches.

Then, polishing liquids were prepared in the same manner as described above except that the abrasive grains No. 21 was employed, and the concentration thereof was changed to 1% by weight and to 10% by weight. Using these polishing liquids, the polishing of an SiOC film was performed under the same conditions as described above. As a result, the number of scratches was limited to less than 30.

Further, three kinds of polishing liquids were prepared in the same manner as described above except that the abrasive grains No. 21 was employed, and the kind and concentration of the surfactant were changed. Specifically, the kind and concentration of the surfactant in these polishing liquids were: 0.0001% by weight of PVA, 0.1% by weight of ammonium dodecylbenzene sulfonate, and 1% by weight of ammonium polyacrylate, respectively. Using these polishing liquids, the polishing of an SiOC film was performed under the same conditions as described above. As a result, the number of scratches was limited to less than 10 for each polishing liquid.

### EMBODIMENT 2

Colloidal silica having an average primary particle diameter (d₂) of 15 nm was prepared as a second colloidal silica. As a first colloidal silica, seven kinds of particles differing in average primary particle diameter (d₁) were prepared. Namely, the average primary particle diameter of the second colloidal silica was set to 40 nm, 45 nm, 50 nm, 60 nm, 70 nm, 80 nm and 90 nm.

The first colloidal silica and the second colloidal silica were mixed together in such a way that the mixing ratio (w₁/(w₁+w₂)) thereof would become 0.75, thus preparing seven kinds of abrasive grains. These abrasive grains were respectively mixed with water together with a surfactant and additives to prepare seven kinds of polishing liquids. More specifically, 3% by weight of abrasive grains, 0.01% by weight of polyacrylic acid (surfactant), 0.5% by weight of maleic acid (additive), and 0.2% by weight of hydrogen peroxide additive were incorporated in pure water. Further, with KOH, the pH of these polishing liquids was adjusted to 9, thus preparing these polishing liquids.

Using each polishing liquid, an SiOC film was polished and the generation of scratches on the surface of the SiOC film after the polishing was investigated in the same manner as described in Embodiment 1. The number of scratches per sheet of wafer was evaluated according to the same criterion as described above, the results thus obtained being summarized in the following Table 3.

TABLE 3

| d₁ (nm) | Scratch |
|---|---|
| 40 | X |
| 45 | Δ |
| 50 | ⊚ |
| 60 | ⊚ |
| 70 | ◯ |
| 80 | Δ |
| 90 | X |

As shown in above Table 3, when the second colloidal silica having an average primary particle diameter (d₂) of 15 nm was employed and the mixing ratio (w₁/(w₁+w₂)) was set to 0.75, it was possible to suppress the generation of scratches within the tolerance limits as long as an average primary particle diameter (d₁) of the first colloidal silica was limited to range from 45 to 80 nm.

Particularly, when the first colloidal silica having an average primary particle diameter (d₁) ranging from 50 to 60 nm was employed, it was possible to greatly minimize the generation of scratches.

Although various kinds of additives, such as an oxidizing agent and an organic acid (oxidation inhibitor), were incorporated in the polishing liquids employed in this embodiment, the surface of SiOC film was not badly affected (with respect to the generation of scratches) by the existence of these additives. When an oxidizing agent or an oxidation inhibitor is incorporated in the polishing liquid according to the embodiment of the present invention, the resultant polishing liquid can be employed also as a touch-up liquid for polishing metallic films such as a barrier metal, a Cu film, etc.

### EMBODIMENT 3

A method of manufacturing a semiconductor device according to this embodiment will be explained.

First of all, as shown in FIG. 2, an insulating film 11 comprising SiO₂ was deposited on a semiconductor substrate 10 having semiconductor elements (not shown) formed therein. Then, plugs 13 were formed with a barrier metal 12 being interposed between the insulating film 11 and the plugs 13. As the barrier metal 12, TiN was employed, and as the plugs 13, W was employed. Further, a first low dielectric constant insulating film 14 and a second low dielectric constant insulating film 15 were successively deposited on the surface, thus forming a laminated insulating film. This first low dielectric constant insulating film 14 may be constituted by a low dielectric constant insulating material having a relative dielectric constant of less than 2.5.

For example, the first low dielectric constant insulating film 14 can be formed by at least one selected from the group consisting of a film having a siloxane skeleton, such as polysiloxane, hydrogen silsesquioxane, polymethyl siloxane, methyl silsesquioxane, etc.; a film comprising, as a major component, an organic resin such as polyarylene ether, polybenzooxazole, polybenzocyclobutene, etc.; and a porous film such as a porous silica film, etc. Herein, polyarylene ether was employed to form the first low dielectric constant insulating film 14 having a film thickness of 180 nm.

The second low dielectric constant insulating film 15 formed on this first low dielectric constant insulating film 14 acts as a capping insulating film and can be constituted by an insulating material having a larger relative dielectric constant than that of the first low dielectric constant insulating film 14. Herein, SiOC was employed to form the second low dielectric constant insulating film 15 having a film thickness of 40 nm. If it is difficult to perform channeling (recess-forming work), a third insulating film formed of an SiO₂ film may be deposited on this second low dielectric constant insulating film 15.

Wiring trenches as recesses were formed in these second low dielectric constant insulating film 15 and first low dielectric constant insulating film 14. Then, a Ta film acting as a barrier metal 16 and having a thickness of 5 nm was deposited on the surface by the conventional method. On this barrier metal 16, a Cu film 17 having a thickness of 550 nm was further deposited.

Then, the Cu film 17 was removed by CMP using a Cu film polishing liquid, thereby exposing the surface of barrier metal 16 while filling the wiring trenches with the Cu film 17 as shown in FIG. 3. The Cu film polishing liquid was prepared as follows. Namely, pure water, CMS7501 (JSR Co., Ltd.) and CMS7552 (JSR Co., Ltd.) were mixed together at a weight ratio of 2:1:1 to obtain a mixture to which 4% by weight of an aqueous solution of ammonium persulfate was added at a weight ratio of 1:1, thus preparing the Cu film polishing liquid.

The polishing of the Cu film 17 was performed, as explained with reference to FIG. 1, under the conditions wherein a turntable 4 having a polishing pad (IC1000: Nitta Haas Co., Ltd.) 5 attached thereto was kept rotating at a rotational speed of 100 rpm, and a top ring 7 holding a semiconductor substrate 6 was in contact with the polishing pad 5 at a polishing load of 250 gf/cm². The rotational speed of the top ring 7 was set to 102 rpm and the polishing liquid was fed onto the polishing pad 5 at a flow rate of 300 cc/min. The polishing of this Cu film 17 was continued until the barrier metal 16 was exposed.

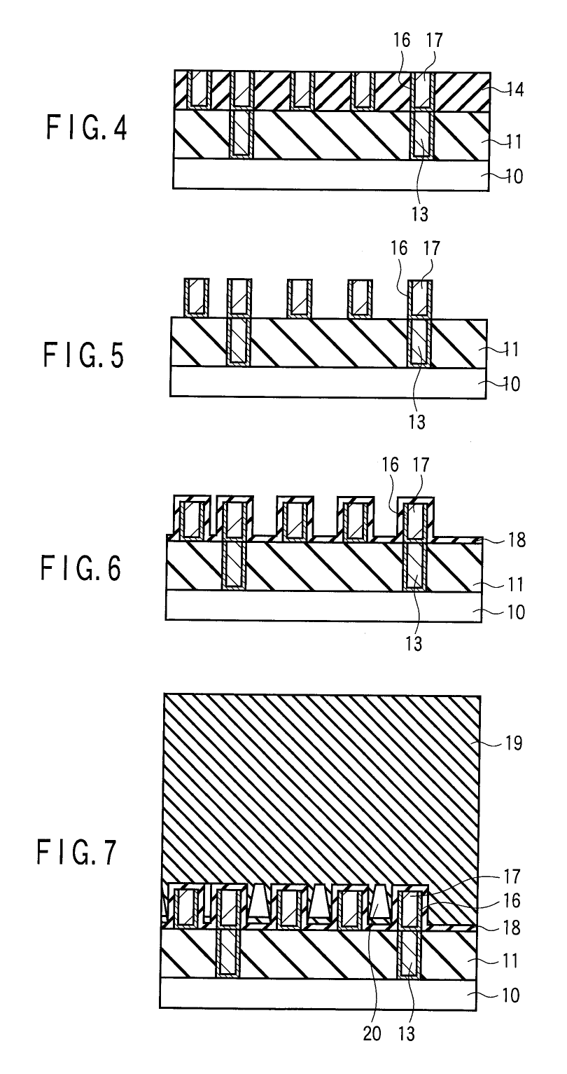

Thereafter, the redundant portions of the Cu film 17, the barrier metal 16 and the second low dielectric constant insulating film 15 were removed by CMP using a polishing liquid to expose the first low dielectric constant insulating film 14 as shown in FIG. 4.

A polishing liquid was prepared by incorporating two kinds of colloidal silica differing in average primary particle diameter from each other and a surfactant in water. More specifically, 5% by weight of the first colloidal silica having an average primary particle diameter of 50 nm and 2% by weight of the second colloidal silica having an average primary particle diameter of 15 nm were dispersed in pure water to obtain a dispersion to which 0.005% by weight of acetylenediol ethylene oxide adduct (HLB value: 18) as a surfactant was added to obtain a mixture. Further, 0.5% by weight of maleic acid as an oxidation inhibitor and 0.2% by weight of hydrogen peroxide as a Cu-oxidizing agent were added to the mixture. Then, the pH of the resultant mixture was adjusted to 10 with potassium hydroxide, thereby preparing a polishing liquid according to this embodiment, which will be hereinafter referred to as a touch-up polishing liquid.

Using the polishing liquid thus obtained, the polishing was performed in the same manner as explained with reference to FIG. 1. More specifically, while feeding the polishing liquid onto the polishing pad (IC1000: Nitta Haas Co., Ltd.) 5 at a flow rate of 300 cc/min., the top ring 7 holding a semiconductor substrate 6 was in contact with the polishing pad 5 at a polishing load of 200 gf/cm². While the turntable 4 was kept rotating at 100 rpm, the top ring 7 was rotated at 102 rpm to perform the polishing for 60 seconds, thereby exposing the first low dielectric constant insulating film 14 as shown in FIG. 4.

Then, the etching by ammonia plasma was performed to remove the first low dielectric constant insulating film 14 as shown in FIG. 5. As a result, rib-like wirings each constituted by the Cu film 17 and the barrier metal 16 was formed on the insulating film 11 as shown in FIG. 5.

After an SiCN film 18 was deposited on the rib-like wirings as well as on the insulating film 11 as shown in FIG. 6, an SiOC film 19 was formed on the surface as shown in FIG. 7. The SiCN film 18 was an insulating film acting as a diffusion barrier for Cu and was deposited to a thickness of 30 nm. The SiOC film 19 formed on this SiCN film 18 was deposited to a thickness of 250 nm having a void space 20 between neighboring rib-like wirings for minimizing parasitic capacity between the wirings.

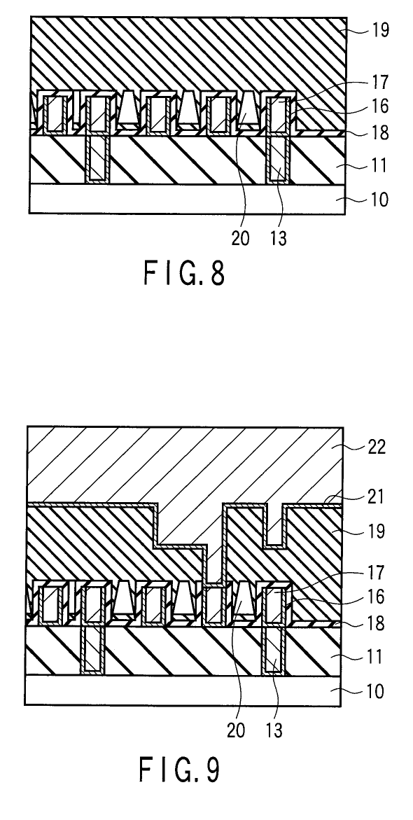

The SiOC film 19 was then subjected to CMP for 120 seconds using the aforementioned touch-up polishing liquid, thereby performing the polishing as shown in FIG. 8. As already explained above, it was possible to use the polishing liquid according to this embodiment for the touch-up since a Cu-oxidizing agent was further incorporated in this polishing liquid. In this case also, the generation of scratches on the surface of SiOC film could be suppressed. On the occasion of this polishing, if scratches generate on the surface of the SiOC film, they may become a cause for the generation of short-circuits among the wiring of the second layer. According to this embodiment, it was possible to avoid this short-circuit problem.

The SiOC film 19 thus polished was then worked to have wiring trenches and via holes, after which a barrier metal 21 and a wiring material film 22 were deposited on the surface as shown in FIG. 9. In this embodiment, the wiring material film 22 was formed of a Cu film. However, the wiring material film 22 may be formed by an alloy containing Cu as a major component or by a metal such as Al, Mn, Ag, Pd, Ni and Mg. The barrier metal 21 may be formed by a metal selected from Ta, Ti, V, Nb, Mo, W and Ru; or by nitrides of these metals. These materials can be formed as a mono-ply film or as a laminated film to create the barrier metal 21.

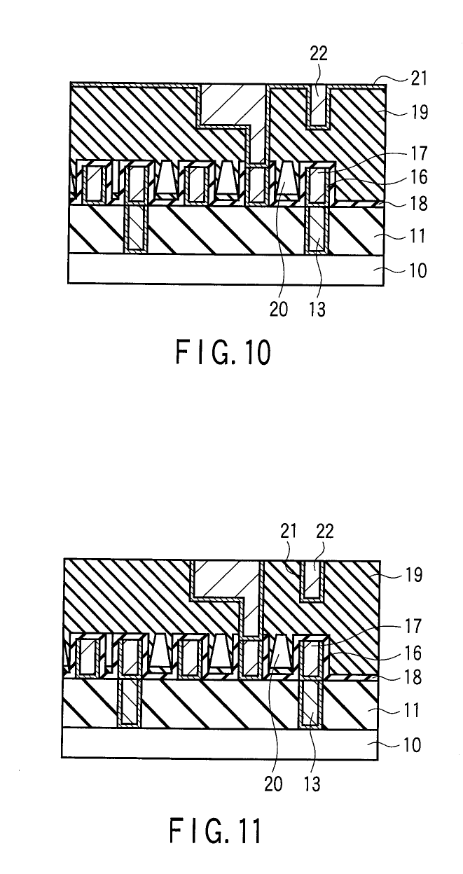

Then, using the aforementioned Cu film polishing liquid, the CMP of the wiring material film 22 was performed to expose the barrier metal 21 as shown in FIG. 10. The conditions for the polishing of the wiring material film 22 may be the same as described above.

Finally, using the aforementioned touch-up polishing liquid, redundant portions of the wiring material film 22 and the barrier metal 21 were removed according to the same method as described above to expose the SiOC film 19 as shown in FIG. 11. On the occasion of this polishing also, if scratches generate on the surface of the SiOC film, they may become a cause for the generation of short-circuits among the wirings. According to this embodiment, it was possible to avoid this short-circuit problem. As a result, it was possible to obtain a multi-layer wiring having air gaps in the lower wiring and having, as an upper layer, an SiOC film of homogenous structure which was capable of suppressing the parasitic capacity of the wiring.

According to this embodiment, since the generation of scratches on the surface of SiOC film can be sufficiently inhibited, it is possible to manufacture a high-performance/high-speed semiconductor device having, for example, a homogenous structure provided with air gaps that the semiconductor device of the next generation is demanded to have. Therefore, the present invention is very valuable from an industrial viewpoint.

As described above, according to one embodiment of the present invention, it is possible to provide a polishing liquid which is capable of polishing an SiOC film while making it possible to remarkably minimize the generation of scratches. According to another embodiment of the present invention, it is possible to provide a method of manufacturing a semiconductor device which is excellent in reliability.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A polishing liquid comprising:
abrasive grains containing a first colloidal silica having an average primary particle diameter of 45-80 nm and a second colloidal silica having an average primary particle diameter of 10-25 nm, the weight w₁ of the first colloidal silica and the weight w₂ of the second colloidal silica satisfying the relationship represented by the following expression 1; and
a surfactant:
0.63≦w₁/(w₁+w₂)≦0.83 Expression 1.

2. The polishing liquid according to claim 1, wherein the first colloidal silica has an average primary particle diameter of 50-60 nm.

3. The polishing liquid according to claim 1, wherein the second colloidal silica has an average primary particle diameter of 15-20 nm.

4. The polishing liquid according to claim 1, wherein the weight w₁ of the first colloidal silica and the weight w₂ of the second colloidal silica satisfy the relationship represented by the following expression 2;
0.67≦w₁/(w₁+w₂)≦0.77 Expression 2

5. The polishing liquid according to claim 1, wherein the abrasive grains are included at a content of 1-10% by weight based on a total weight of the polishing liquid.

6. The polishing liquid according to claim 1, wherein the surfactant is selected from the group consisting of dodecylbenzene sulfonic acid and salts thereof, polyacrylic acid and salts thereof, polyoxyethylene alkylamine, polyoxyethylene lauryl ether, acetylenediol-based ethylene oxide adduct, perfluoroalkyl ethylene oxide adduct, polyvinylpyrrolidone and polyvinyl alcohol.

7. The polishing liquid according to claim 1, wherein the surfactant is included at a content of 0.0001-1% by weight based on a total weight of the polishing liquid.

8. The polishing liquid according to claim 1, further comprising an oxidizing agent and an oxidation inhibitor.

9. The polishing liquid according to claim 1, wherein the polishing liquid has a pH ranging from 8 to 11.

10. A method for manufacturing a semiconductor device, comprising:
forming a plurality of rib-like wirings above a semiconductor substrate;
depositing an SiOC film above the rib-like wirings while creating a void space between neighboring rib-like wirings; and
polishing the SiOC film with a polishing liquid, the polishing liquid comprising abrasive grains containing a first colloidal silica having an average primary particle diameter of 45-80 nm and a second colloidal silica having an average primary particle diameter of 10-25 nm, the weight w₁ of the first colloidal silica and the weight w₂ of the second colloidal silica satisfying the relationship represented by the following expression 1; and a surfactant:
0.63≦w₁/(w₁+w₂)≦0.83 Expression 1.

11. A method for manufacturing a semiconductor device, comprising:
depositing a wiring material film above an SiOC film having a recess and in the recess with a barrier metal being interposed between the wiring material film and the SiOC film, the SiOC film being formed above a semiconductor substrate;
removing the wiring material film except the wiring material film deposited in the recess, thereby leaving the wiring material film in the recess while selectively exposing the barrier metal; and
polishing and removing the barrier metal except the barrier metal deposited in the recess with a polishing liquid, thereby exposing the SiOC film, the polishing liquid comprising abrasive grains containing a first colloidal silica having an average primary particle diameter of 45-80 nm and a second colloidal silica having an average primary particle diameter of 10-25 nm, the weight w₁ of the first colloidal silica and the weight w₂ of the second colloidal silica satisfying the relationship represented by the following expression 1; a surfactant; an oxidizing agent; and an oxidation inhibitor:
0.63≦w₁/(w₁+w₂)≦0.83 Expression 1.

12. The method according to claim 11, wherein the abrasive grains are included at a content of 1-10% by weight based on a total weight of the polishing liquid.

13. The method according to claim 11, wherein the surfactant is selected from the group consisting of dodecylbenzene sulfonic acid and salts thereof, polyacrylic acid and salts thereof, polyoxyethylene alkylamine, polyoxyethylene lauryl ether, acetylenediol-based ethylene oxide adduct, perfluoroalkyl ethylene oxide adduct, polyvinylpyrrolidone and polyvinyl alcohol.

14. The method according to claim 11, wherein the surfactant is included at a content of 0.0001-1% by weight based on a total weight of the polishing liquid.

15. The method according to claim 11, wherein the oxidizing agent is selected from the group consisting of ammonium persulfate, potassium persulfate and hydrogen peroxide.

16. The method according to claim 11, wherein the oxidizing agent is included at a content of 0.1-5% by weight based on a total weight of the polishing liquid.

17. The method according to claim 11, wherein the oxidation inhibitor is selected from organic acid and amino acid.

18. The method according to claim 11, wherein the oxidation inhibitor is included at a content of 0.01-3% by weight based on a total weight of the polishing liquid.

19. The method according to claim 17, wherein the organic acid is selected from the group consisting of heterocyclic organic compounds, malonic acid, oxalic acid, citric acid, maleic acid, phthalic acid, nicotinic acid, picolinic acid and succinic acid.

20. The method according to claim 17, wherein the amino acid is selected from glycine and alanine.
